(19) United States
(12) Patent Application Publication
(10) Pub. No.: US 2015/0130489 A1
(43) Pub. Date: May 14, 2015

(54) SUBSTRATE INSPECTION APPARATUS

(71) Applicant: Tokyo Electron Limited, Tokyo (JP)

(72) Inventor: Hiroshi Yamada, Nirasaki-shi (JP)

(73) Assignee: Tokyo Electron Limited, Tokyo (JP)

(21) Appl. No.: 14/405,348

(22) PCT Filed: May 31, 2013
(86) PCT No.: PCT/JP2013/065767

§ 371 Date: Dec. 3, 2014

(30) Foreign Application Priority Data
Jun. 4, 2012 (JP) 2012-127435

(51) Int. Cl. G01R 31/28; G01R 1/067

(52) U.S. Cl. CPC G01R 31/2891; G01R 1/06705
USPC 324/754.11

(57) ABSTRACT

A probe apparatus 10 that maintains a contact state between each of probes 15 of a probe card 17 and each of corresponding electrodes of semiconductor devices formed on a wafer W by maintaining a decompressed state of a sealed space S between the wafer W and the probe card 17 includes an ejector 23 configured to decompress the sealed space S. Further, the ejector 23 includes a suction port 29; a decompression chamber 31 communicating with the suction port 29; an exhaust port 34 communicating with the decompression chamber 31; and a nozzle 32 through which air is discharged toward the decompression chamber 31 at a high velocity. Furthermore, the nozzle 32 is configured to directly confront the exhaust port 34, and the suction port 29 communicates with the sealed space S.

### TECHNICAL FIELD

The embodiments described herein pertain generally to a substrate inspection apparatus having a probe card.

### BACKGROUND

As a substrate inspection apparatus, for example, there is known a probe apparatus that inspects electrical characteristics of a multiple number of semiconductor devices formed on a wafer as a substrate.

Typically, the probe apparatus includes a stage that can be moved in X, Y, Z and θ directions while mounting the wafer thereon; a head plate provided above the stage; and a probe card provided to the head plate to face the stage. The probe card has a multiple number of probes (inspection needles) protruding toward the stage.

In this probe apparatus, alignment (position adjustment) between the probes of the probe card and corresponding electrodes of the semiconductor devices formed on the wafer is performed by moving the stage relatively with respect to the head plate. Then, by moving the stage upward, each probe of the probe card and each corresponding electrode on the wafer are brought into contact with each other, and electrical characteristics of the multiple semiconductor devices formed on the wafer are inspected.

Typically, in the probe apparatus, the wafer is pressed against the probe card by mechanically moving the stage in the Z direction. Since, however, a contact surface formed by leading ends of the individual probes and a mounting surface of the stage on which the wafer is mounted are not always parallel to each other, a part of the multiple number of probes and a part of a multiple number of electrodes of the semiconductor devices may be brought into excessively strong contact with each other, whereas another part of the multiple number of probes and another part of the electrodes may not be brought into contact with each other at all. That is, all the probes may not be brought into contact with the corresponding electrodes of the semiconductor devices in a uniform manner.

To solve the problem, there has been proposed a probe apparatus in which a sealed space is formed between the probe card and a wafer tray on which a wafer is mounted. In this apparatus, the wafer on the wafer tray is attracted to the probe card by decompressing the sealed space (see, for example Patent Document 1).

Since a pressure within the sealed space is uniform, the entire surface of the wafer can be attracted to the probe card by a uniform force, so that all probes can be brought into contact with corresponding electrodes of semiconductor devices in a substantially uniform manner. In this probe apparatus, a negative pressure generated by an electro-pneumatic regulator is used to decompress the sealed space.

### REFERENCES

Patent Document 1: Japanese Patent Laid-open Publication No. 2010-186998

### DISCLOSURE OF THE INVENTION

### Problems to be Solved by the Invention

In the electro-pneumatic regulator, however, since the negative pressure is generated by opening and closing a multiple number of valves provided in the electro-pneumatic regulator, a pressure control range is large, and it is difficult to generate a negative pressure having a small absolute value.

If the absolute value of the negative pressure is large, the decompression range of the sealed space may also be large, and the probes and the corresponding electrodes of the semiconductor devices may be brought into excessively strong contact with each other. As a result, deep needle marks may be left on the electrodes, and the probes or the wafer may be damaged.

In view of the foregoing problems, example embodiments provide a substrate inspection apparatus capable of suppressing a probe or a substrate from being damaged without leaving a deep needle mark on each electrode of a semiconductor device on the substrate.

### Means for Solving the Problems

In one example embodiment, a substrate inspection apparatus that maintains a contact state between each of probes of a probe card and each of corresponding electrodes of semiconductor devices formed on a substrate by maintaining a decompressed state of a sealed space between the substrate and the probe card includes a decompressing device configured to decompress the sealed space. Further, the decompressing device includes a suction opening; a decompression chamber communicating with the suction opening; an exhaust opening communicating with the decompression chamber; and a discharge opening through which a fluid is discharged toward the decompression chamber at a high velocity. Furthermore, the discharge opening is configured to directly confront the exhaust opening, and the suction opening communicates with the sealed space.

In the example embodiment, the fluid may be discharged from the discharge opening by using a positive pressure generated through an electro-pneumatic regulator.

In the example embodiment, after each electrode of the semiconductor devices formed on the substrate is brought into contact with each corresponding probe of the probe card by moving the substrate toward the probe card, the substrate may further be moved toward the probe card by a preset distance.

In the example embodiment, the preset distance may be set to be in a range from 10 μm to 150 μm.

### Effect of the Invention

In accordance with the example embodiments, the decompressing device configured to decompress the sealed space between the substrate and the probe card includes the suction opening; the decompression chamber communicating with the suction opening; the exhaust opening communicating with the decompression chamber; and the discharge opening configured to discharge a fluid toward the decompression chamber at a high velocity. Since the discharge opening and the exhaust opening are formed to directly confront with each other, the high-velocity fluid draws a gas within the decompression chamber, and then, the drawn gas is exhausted through the exhaust opening. As a result, a negative pressure is generated in the decompression chamber and, also, in the suction opening communicating with the decompression chamber. The amount of the gas drawn from the decompression chamber is smaller than the amount of the high-velocity fluid discharged from the discharge opening. Accordingly, even if the amount of the high-velocity fluid discharged from the discharge opening is greatly varied, the amount of the gas drawn from the decompression chamber is still small. Since there is a correlation between the amount of the gas drawn from the decompression chamber and the variation range of the negative pressure in the suction opening, the control range of the negative pressure in the suction opening can be reduced, so that the decompression range of the sealed space can also be reduced. As a consequence, it is possible to suppress the strong contact between each probe and each corresponding electrode of each semiconductor device. Accordingly, when inspecting electrical characteristics of each semiconductor device on the substrate, deep needle marks may not be left on each electrode of each semiconductor device on the substrate, and the probe or the substrate can be suppressed from being damaged.

### BRIEF DESCRIPTION OF THE DRAWINGS

FIG. 1 is a cross sectional view schematically illustrating a configuration of a substrate inspection apparatus in accordance with an example embodiment.

FIG. 2 is a cross sectional view schematically illustrating a configuration of an ejector of FIG. 1.

FIG. 3A to FIG. 3C are process diagrams illustrating a wafer attracting process performed in a probe apparatus of FIG. 1.

### MODE FOR CARRYING OUT THE INVENTION

Hereinafter, example embodiments will be explained with reference to the accompanying drawings, which form a part hereof.

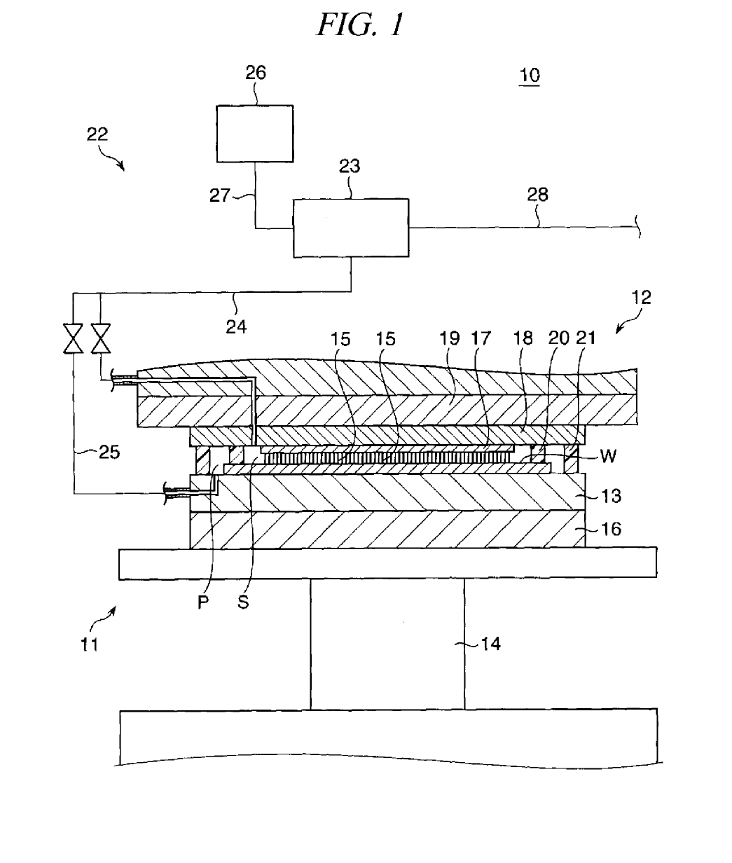

FIG. 1 is a cross sectional view schematically illustrating a configuration of a substrate inspection apparatus in accordance with an example embodiment.

In FIG. 1, a probe apparatus 10 serving as a substrate inspection apparatus includes a stage 11 configured to mount thereon a wafer W to be inspected; and an inspection unit 12 provided to face the stage 11.

The stage 11 includes a wafer plate 13 made of a plate-shaped member configured to mount thereon the wafer W (substrate) directly; a shaft 14 configured to move the wafer plate 13 in a vertical direction of the drawing; and a plate-shaped chuck member 16 provided on a leading end of the shaft 14 and configured to attract the wafer plate 13.

The inspection unit 12 includes a probe card 17 placed to face the wafer W mounted on the wafer plate 13; a contact plate 18 made of a plate-shaped member; and a head plate 19 made of a plate-shaped member and configured to suspend the contact plate 18. The probe card 17 is provided on a bottom surface of the contact plate 18.

The contact plate 18 and the head plate 19 include a pogo pin (not shown), which is a bundle of pins connected to individual probes 15 of the probe card 17, and the pogo pin is connected to an electrical characteristic inspection circuit (not shown).

In this probe apparatus 10, the wafer plate 13 is moved toward the probe card 17 by the shaft 14, and each of electrodes (not shown) of semiconductor devices formed on a front surface (top surface in this drawing) of the wafer W is brought into contact with each of corresponding probes (inspection needles) 15 of the probe card 17.

At this time, an inner lip 20, which is an annular seal member surrounding the probe card 17, is provided between the wafer W and the contact plate 18 and configured to seal a sealed space S between the wafer W and the probe card 17. Further, an outer lip 21, which is an annular seal member surrounding the wafer W, is also provided between the wafer plate 13 and the contact plate 18. Since the outer lip 21 and the inner lip 20 are arranged substantially concentrically, the outer lip 21 also seals the sealed space S from the outside of the inner lip 20. That is, the sealed space S is doubly sealed by the inner lip 20 and the outer lip 21.

Further, the probe apparatus 10 includes a decompression system 22 configured to maintain a decompressed state of the sealed space S. The decompression system 22 includes an ejector 23 as a decompressing device; a first decompression line 24 communicating with the ejector 23 and the sealed space 5; a second decompression line 25 which is branched from the first decompression line 24 and communicates with a sub-sealed space P between the inner lip 20 and the outer lip 21; an electro-pneumatic regulator 26 configured to generate a positive pressure to be supplied to the ejector 23; a pressure pipe 27 communicating with the electro-pneumatic regulator 26 and the ejector 23; and a gas exhaust line 28 connected to the ejector 23.

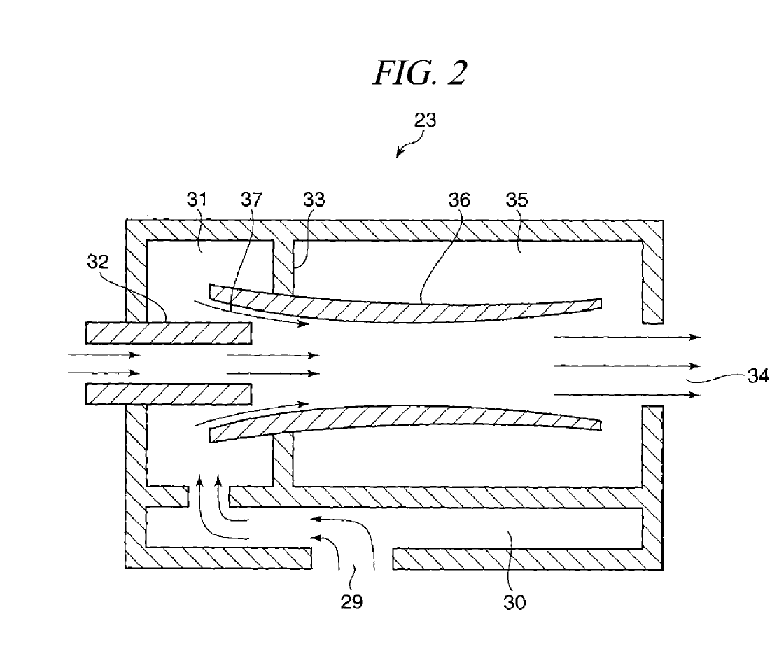

FIG. 2 is a cross sectional view illustrating a configuration of the ejector shown in FIG. 1.

In FIG. 2, the ejector 23 is formed of a cylindrical vessel and includes a suction chamber 30 having a suction port 29 (suction opening); a decompression chamber 31 communicating with the suction chamber 30; a nozzle 32 (discharge opening) provided at the decompression chamber 31; exhaust chamber 35 which is arranged to be adjacent to the decompression chamber 31 via a partition wall 33 and has an exhaust port 34 (exhaust opening) directly confronting the nozzle 32; and a cylindrical diffuser 36 penetrating the partition wall 33 and allowing the decompression chamber 31 and the exhaust chamber 35 to communicate with each other. Since the diffuser 36 is arranged coaxially with respect to the nozzle 32, one end of the diffuser 36 within the exhaust chamber 35 directly confronts the exhaust port 34.

A diameter of the other end (hereinafter, referred to as “suction end”) of the diffuser 36 within the decompression chamber 31 is larger than a diameter of the nozzle 32. Accordingly, an end of the nozzle 32 can be inserted into the suction end. Since, however, the nozzle 32 is not in contact with the diffuser 36, a gap 37 is formed between the suction end of the diffuser 36 and the nozzle 32.

The pressure pipe 27 is connected to the nozzle 32, and a fluid having a positive pressure, e.g., air, generated by the electro-pneumatic regulator 26 is supplied into the nozzle 32. Since a pressure control range of the electro-pneumatic regulator 26 is large, an absolute value of the positive pressure generated by the electro-pneumatic regulator 26 is also large. Accordingly, the positive-pressure air supplied into the nozzle 32 is discharged toward the decompression chamber 31 at a high velocity. Since the end of the nozzle 32 is inserted into the suction end, the air discharged from the nozzle 32 passes through the inside of the diffuser 36, and then, is exhausted to the outside of the ejector 23 through the exhaust port 34. Here, since the diffuser 36 is designed such that a diameter of a middle portion of the diffuser 36 is narrower than both end portions thereof, the air discharged from the nozzle 32 is accelerated. The accelerated air passing through the diffuser 36 at a high velocity draws air within the decompression chamber 31 into the diffuser 36 from the gap 37, and the drawn air is directly exhausted through the exhaust port 34. Accordingly, a negative pressure is generated within the decompression chamber 31, and a negative pressure is also generated in the suction chamber 30 communicating with the decompression chamber 31 and, besides, in the suction port 29. As a result, the sealed space S and the sub-sealed space P are decompressed through the first decompression line 24 and the second decompression line 25, respectively. The flow of the air within the ejector 23 is indicated by arrows in FIG. 2.

Here, since the gap 37 in the ejector 23 is set not to be large, the amount of the air in the decompression chamber 31 drawn into the diffuser 36 from the gap 37 is smaller than the amount of the air discharged from the nozzle 32. Further, there is a correlation between the amount of the air in the decompression chamber 31 drawn into the diffuser 36 and the variation range of the negative pressure generated in the suction port 29. As a result, the control range of the negative pressure in the suction port 29 can be reduced, so that the decompression range of the sealed space S and the sub-sealed space P can also be reduced.

As a consequence, the wafer W is not strongly attracted to the probe card 17, so that it is possible to suppress the strong contact between each probe 15 and each corresponding electrode of each semiconductor device. Accordingly, when inspecting electrical characteristics of each semiconductor device of the wafer W, deep needle marks may not be left on the electrodes of the semiconductor devices of the wafer W, and the probe 15 or the substrate can be suppressed from being damaged.

When generating the negative pressure by the ejector 23, the positive pressure generated by the electro-pneumatic regulator 26 is utilized. Since the electro-pneumatic regulator 26 generates the positive pressure by opening and closing a multiple number of valves (not shown) included therein, the positive pressure can be generated easily. That is, since the positive-pressure air can be easily supplied into the nozzle 32 of the ejector 23, a required negative pressure can be easily obtained in the ejector 23.

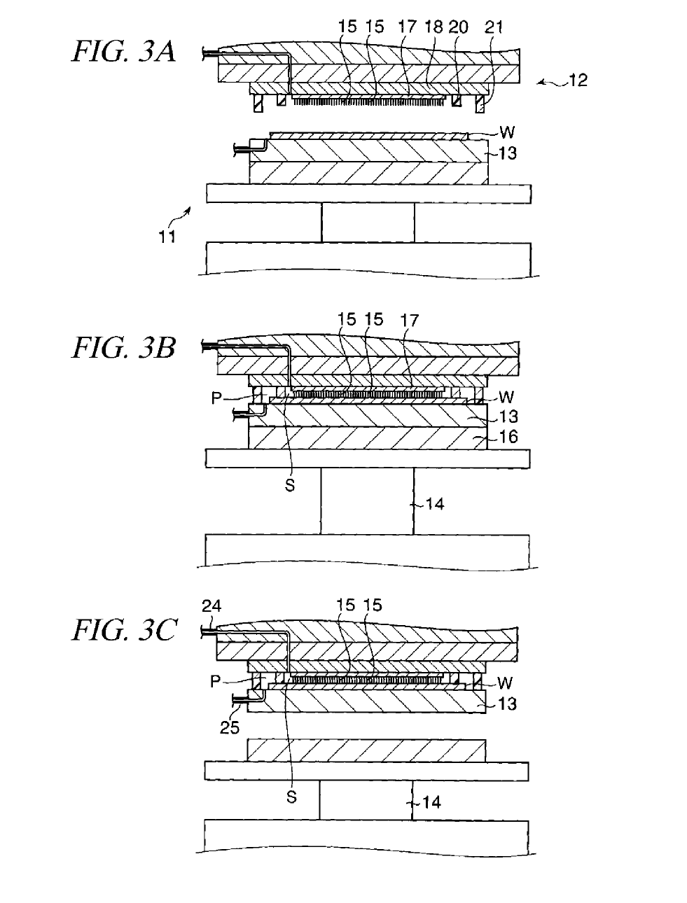

FIG. 3A to FIG. 3C are process diagrams illustrating a wafer attracting process performed in the probe apparatus of FIG. 1.

First, a wafer W is mounted on the stage 11 which is spaced apart from the inspection unit 12 and attracted to the wafer plate 13. Then, the stage 11 is moved in a horizontal direction in the drawing, so that electrodes of each semiconductor device formed on a surface of the wafer W are allowed to face corresponding probes 15 of the probe card 17 (FIG. 3A). Further, the inner lip 20 and the outer lip 21 are provided on the contact plate 18.

Subsequently, the shaft 14 moves the chuck member 16 and the wafer plate 13 toward the probe card 17 in the vertical direction, so that the electrodes of each semiconductor device of the wafer W are allowed to come into contact with the corresponding probes 15 of the probe card 17. Then, the shaft 14 moves the wafer plate 13 upward in the drawing about 10 μm to 150 μm. Therefore, the probes 15 and the corresponding electrodes of each semiconductor device can be brought into secure contact with each other.

When each electrode of each semiconductor device is brought into contact with each corresponding probe 15, the inner lip 20 comes into contact with the wafer W to form the sealed space S, and the outer lip 21 comes into contact with the wafer plate 13 to form the sub-sealed space P (FIG. 3B).

Then, by supplying positive-pressure air into the nozzle 32 of the ejector 23 from the electro-pneumatic regulator 26, a negative pressure is generated in the suction port 29 of the ejector 23, and the sealed space S and the sub-sealed space P are decompressed through the first decompression line 24 and the second decompression line 25, respectively. The decompressed sub-sealed space P allows the wafer plate 13 to be suspended, and the decompressed sealed space S maintains the contact state between the probes 15 and the corresponding electrodes of each semiconductor device (FIG. 3B).

Then, the attraction of the wafer plate 13 by the chuck member 16 is released, and the shaft 14 moves the chuck member 16 downward in the drawing, so that the chuck member 16 is spaced apart from the wafer plate 13 (FIG. 3C). Accordingly, the wafer plate 13 faces the sealed space S alone. At this time, since the chuck member 16 is spaced apart from the wafer plate 13, the wafer plate 13 may be easily transformed to conform to the contact surface formed by the leading ends of the individual probes 15. As a result, the wafer W attracted to the wafer plate 13 is also transformed to conform to the contact surface, so that all the probes 15 can be brought into secure contact with all the corresponding electrodes of the all the semiconductor devices.

Thereafter, electrical characteristics of each semiconductor device are inspected by applying electricity from each probe 15 to each corresponding electrode of the semiconductor device. Then, this process is ended.

In the above, the example embodiment has been described. However, the example embodiment is not intended to be limiting.

In the above-described example embodiment, the single probe apparatus 10 has a single set of the stage 11 and the inspection unit 12. However, the probe apparatus may have a frame in the form of shelves having a multiple number of chambers, and the set of the stage 11 and the inspection unit 12 may be provided in each chamber. In this configuration, the ejector 23 may be commonly shared by the individual sets of the stage 11 and the inspection unit 12.

This international application claims priority to Japanese Patent Application No. 2012-127435, filed on Jun. 4, 2012, which application is hereby incorporated by reference in its entirety.

### EXPLANATION OF REFERENCE NUMERALS

S: Sealed space

W: Wafer

10: Probe apparatus

15: Probe

17: Probe card

23: Ejector

29: Suction port

31: Decompression chamber

32: Nozzle

34: Exhaust port

1. A substrate inspection apparatus that maintains a contact state between each of probes of a probe card and each of corresponding electrodes of semiconductor devices formed on a substrate by maintaining a decompressed state of a sealed space between the substrate and the probe card, the substrate inspection apparatus comprising:
a decompressing device configured to decompress the sealed space,
wherein the decompressing device includes a suction opening; a decompression chamber communicating with the suction opening; an exhaust opening communicating with the decompression chamber; and a discharge opening through which a fluid is discharged toward the decompression chamber at a high velocity,
the discharge opening is configured to directly confront the exhaust opening, and
the suction opening communicates with the sealed space.

2. The substrate inspection apparatus of claim 1,
wherein the fluid is discharged from the discharge opening by using a positive pressure generated through an electro-pneumatic regulator.

3. The substrate inspection apparatus of claim 1,
wherein, after each electrode of the semiconductor devices formed on the substrate is brought into contact with each corresponding probe of the probe card by moving the substrate toward the probe card, the substrate is further moved toward the probe card by a preset distance.

4. The substrate inspection apparatus of claim 3, wherein the preset distance is set to be in a range from 10 μm to 150 μm.
